(19) United States
(12) Patent Application Publication
(10) Pub. No.: US 2023/0035100 A1
(43) Pub. Date: Feb. 2, 2023

(54) heat dissipation and electrical robustness in a three-dimensional package of stacked integrated circuits

(71) Applicant: Marvell Asia Pte Ltd, Singapore (SG)

(72) Inventors: Janak G. Patel, South Burlington, VT (US); Manish Nayini, Wappingers Falls, NY (US); Richard S. Graf, Gray, ME (US); Nazmul Habib, Colchester, VT (US)

(21) Appl. No.: 17/874,345

(22) Filed: Jul. 27, 2022

Related U.S. Application Data
(60) Provisional application No. 63/227,185, filed on Jul. 29, 2021.

(51) Int. Cl. H01L 23/367; H01L 23/373; H01L 25/065; H01L 23/60; H01L 21/48

(52) U.S. Cl. CPC H01L 23/3672; H01L 23/3731; H01L 25/0657; H01L 23/60; H01L 21/4882; H01L 2225/06589; H01L 2225/06513; H01L 2225/06541; H01L 2225/06565

(57) ABSTRACT

An electronic device, including a substrate and a stack of dies stacked on the substrate. The stack of dies includes: (a) one or more functional dies, the functional dies including functional electronic circuits and being configured to exchange electrical signals at least with the substrate, and (b) one or more dummy dies, the dummy dies being disposed among dies forming the stack and being configured to: (i) dissipate heat generated by the one or more functional dies and (ii) pass electrical signals exchanged between the substrate and the one or more functional dies or between two or more of the functional dies.

### CROSS-REFERENCE TO RELATED APPLICATIONS

This application claims the benefit of U.S. Provisional Patent Application 63/227,185, filed Jul. 29, 2021, whose disclosure is incorporated herein by reference.

### FIELD OF THE DISCLOSURE

The present invention relates generally to electronic devices, and particularly to methods and systems for improving heat dissipation and electrical robustness in a three-dimensional (3D) package of stacked integrated circuits (ICs).

### BACKGROUND

Various techniques are known in the art for stacking multiple ICs in electronic devices.

The description above is presented as a general overview of related art in this field and should not be construed as an admission that any of the information it contains constitutes prior art against the present patent application.

### SUMMARY

An embodiment that is described herein provides an electronic device including a substrate, and a stack of dies stacked on the substrate, the stack of dies including: (a) one or more functional dies, the functional dies including functional electronic circuits and. being configured to exchange electrical signals at least with the substrate, and (b) one or more dummy dies, the dummy dies being disposed among dies forming the stack and being configured to: (i) dissipate heat generated by the one or more functional dies and (ii) pass electrical signals exchanged between the substrate and the one or more functional dies or between two or more of the functional dies.

In some embodiments, at least one of the dummy dies includes first and second metal layers, which are: (i) electrically disconnected from one another, (ii) electrically coupled, respectively, to first and second electrical connections of the electronic device, and (iii) configured to dissipate at least part of the heat generated by at least one of the functional dies. In other embodiments, the first electrical connections include one or more power rails electrically coupled to the first metal layer, the second electrical connections include one or more ground rails electrically coupled to the second metal layer, and the first and second metal layers form an intra-stack capacitor for mitigating electrostatic discharge (ESD) effects within the electronic device. In vet other embodiments, the first and second metal layers, form an intra-stack capacitor configured to supply power to at least one of the functional dies.

In some embodiments, the dummy dies include one or both of: (i) a first dummy die disposed between the substrate and a first one of the functional dies, and (ii) second dummy die disposed between two of the functional dies. In other embodiments, the functional dies have a major plane defined by at least first and second axial dimensions, an axial dimension of at least one of the dummy dies is greater than the first or second axial dimensions defining the functional dies. In yet other embodiments, the dummy dies include a first dummy die having a first axial dimension of the first dummy die, which is larger than the first axial dimension of the functional dies, and a second dummy die having a second axial dimension, which is larger than the second axial dimension of the functional dies.

In some embodiments, the electronic device includes a lid, which is configured to: (i) encapsulate at least part of the stack, and (ii) dissipate heat from the electronic device. In other embodiments, at least a part of one of the dummy dies extends laterally beyond an edge of the stack and the lid has at least one opening, the part is extending laterally through the opening, and is thermally coupled to the lid at the opening. In yet other embodiments, the electronic device includes a thermal interface material (TIM) disposed between the lid and the part of one of the dummy dies, the TIM configured to thermally couple between the lid and the part of one of the dummy dies.

In some embodiments, the lid has one or more cooling fins, which are configured to provide an additional surface area on the lid for heat dissipation. In other embodiments, the electronic device includes a stiffener formed between the substrate and the lid, the stiffener being configured to improve a mechanical stiffness of the electronic device. In yet other embodiments, at least one of the dummy dies includes a semiconductor substrate.

In some embodiments, at least one of the dummy dies includes a polymer substrate. In other embodiments, at least one of the dummy dies includes ceramic substrate.

There is additionally provided, in accordance with an embodiment of the present invention, a method for producing an electronic device, the method including disposing, on a substrate a stack of dies, the stack including one or more functional dies, the functional dies including functional electronic circuits for exchanging electrical signals at least with the substrate. One or more dummy dies are disposed on the substrate among the dies forming the stack, the one or more dummy dies are disposed for: (i) dissipating heat generated by the one or more functional dies and (ii) passing electrical signals exchanged between the substrate and the one or more functional dies or between two or more of the functional dies.

The present disclosure will be more fully understood from the following detailed description of the embodiments thereof, taken together with the drawings in which:

### BRIEF DESCRIPTION OF THE DRAWINGS

FIG. 1 is a schematic, sectional view of an electronic device, in accordance with an embodiment that is described herein;

FIG. 2 is a schematic, top view of the electronic device of FIG. 1, in accordance with an embodiment that is described herein;

FIG. 3 is a schematic, sectional view of an electronic device, in accordance with another embodiment that is described herein;

FIG. 4 is a schematic, top view of the electronic device of FIG. 3, in accordance with an embodiment that is described herein;

FIG. 5 is a schematic, pictorial illustration of the electronic device of FIGS. 3 and 4, in accordance with an embodiment that is described herein;

FIG. 6 is a schematic, sectional view of an electronic device, in accordance with another embodiment that is described herein;

FIG. 7 is a schematic, sectional view of an electronic device, in accordance with an alternative embodiment that is described herein; and

FIG. 8 is a flow chart that schematically illustrates a method for producing the electronic device of FIG. 6, in accordance with an embodiment that is described herein.

### DETAILED DESCRIPTION OF EMBODIMENTS

Electronic devices may comprise multiple chips, also referred to herein as functional dies, stacked together over a substrate in a three-dimensional (3D) package. The functional dies are typically formed on a semiconductor (e.g., silicon) substrate, and comprise functional electronic circuits and through-silicon vias (TSVs), and are configured to exchange electrical (e.g., power, ground and data) signals with the substrate, and in some cases, with one another.

Such 3D packages may comprise any suitable number of functional dies, for example, between about two (2) and thirty-two (32) functional dies, depending on the application of the electronic device. While being operated, the electrical current flowing through the functional electronic circuits of each functional die, produces heat.

The stack of functional dies is typically confined between: (i) the substrate, which is typically made from a. polymer matrix and has low thermal conductivity, and (ii) a lid, which is typically made from a suitable metal (e.g., copper) and has high thermal conductivity. In this configuration, the package is configured to dissipate most of the heat through the lid (typically thermally coupled to a heat sink via thermal interface material between lid and heat sink base). Thus, the heat produced by the dies disposed between the substrate and the uppermost die, is confined within the package, and therefore, increases the temperature of the electronic device, and thereby, may impair the functionality and/or reliability of the electronic device.

Moreover, such electronic devices are operating at increasing frequencies, and therefore, are susceptible to electrostatic discharge (ESD) and other capacitance-related effects in addition to the requirement to dissipate the heat.

Embodiments of the present disclosure that are described herein, provide techniques for improving the heat dissipation and mitigating, several undesired electrical effects, such as ESD, in electronic devices comprises a stack of functional dies.

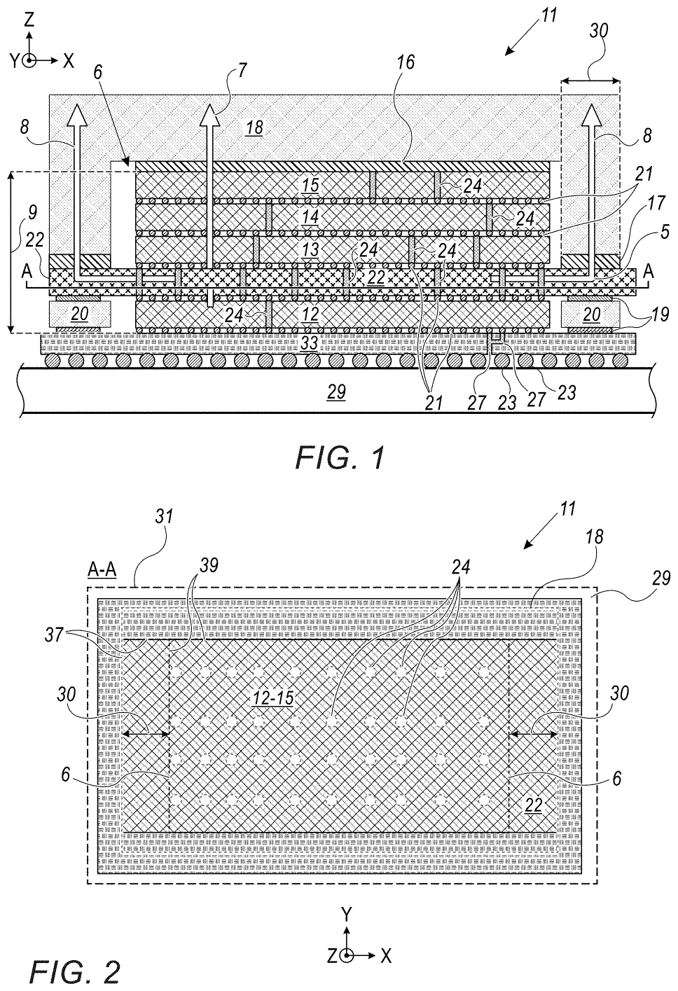

In some embodiments, the electronic device comprises (i) a substrate (e.g., GL-102 Ajinomoto Build-up Film® also referred to herein as ABF). In other embodiments, other ABF materials such as GX13, GZ41 produced by Ajinomoto can also be used. The Build-up film or layers are usually built on both sides of core material such as but not limited to E705G produced by SHOW A DENKO MATERIALS CO., LTD. (Tokyo, Japan), and (ii) a stack of dies stacked on the substrate. The stack comprises one or more functional dies, each comprising a silicon substrate and functional electronic circuits, and configured to exchange electrical signals at least with the substrate. The stack further comprises one or more dummy dies, which are disposed between the substrate and the uppermost functional die, and are configured to: (a) dissipate heat generated by one or more of the functional dies, and (b) conduct electrical signals (e.g., power and data signals, and connected to ground) exchanged between. the substrate and one or more of the functional dies, and/or between two or more of the functional dies. Various configurations of 3D packages having a stack of dies comprising functional dies and. dummy dies are described in detail in FIGS. 1-7 below.

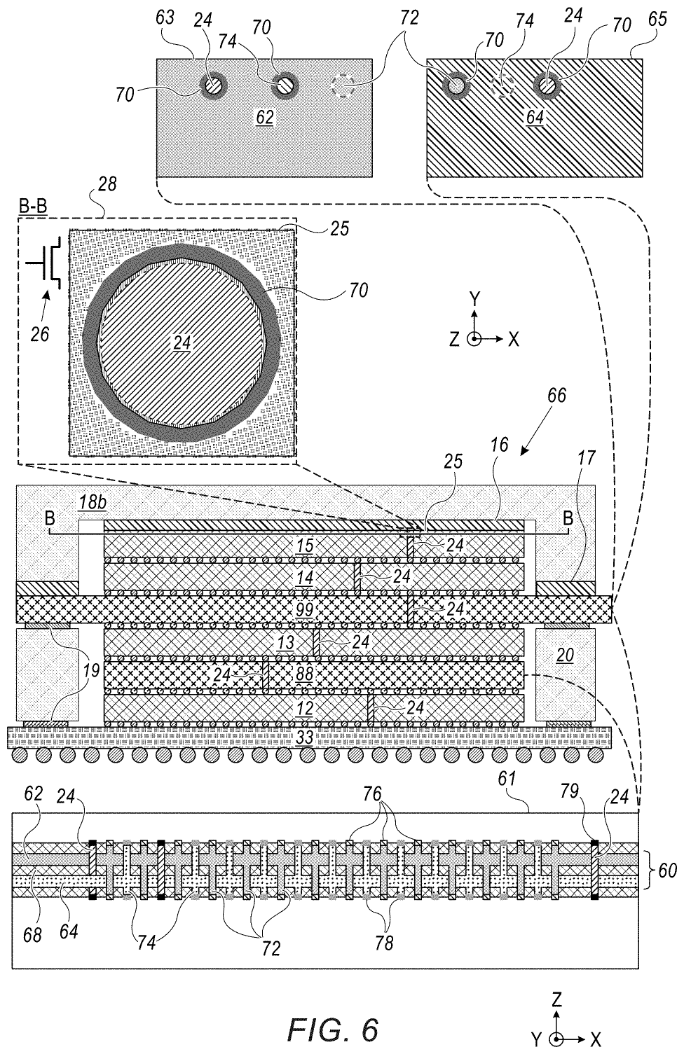

In some embodiments, at least one of the dummy dies comprises first and second metal layers (also referred to herein as power plane and ground plane, respectively), which are electrically disconnected from one another, e.g., using the substrate material of the dummy die (described in detail in FIGS. 1 and 6 below) or any other suitable dielectric layer formed between the first and second metal layers.

In some embodiments, the first and second metal layers are electrically coupled, respectively, to first and second electrical connections of the electronic device. In the present example, the first and second electrical connections are implemented in first and second TSVs, respectively and in bumps formed between each pair of dies disposed in the 3D package.

In some embodiments, the first and second metal layers are configured to dissipate at least part of the heat generated at least by the one or more functional dies. In some embodiments, the first electrical connections (e.g., the first TSVs) comprise one or more power rails that are electrically coupled to the first metal layer. Similarly, the second electrical connections (e.g., the second TSVs) comprise one or more ground rails electrically coupled to the second metal layer.

In the present example, the first and second metal layers form an intra-stack capacitor for mitigating the aforementioned (ESD) effects within the electronic device. Additionally, or alternatively, the intra-stack capacitor formed by the first and second metal layers, is configured to supply power to at least one of the functional dies. The structure and functionality of the intra-stack capacitor, which is implemented in at least one of the dummy dies, is described in detail in FIG. 6 below.

In some embodiments, the substrates of the functional dies and dummy dies have a similar coefficient of thermal expansion (CTE) in order to prevent thermally induced mechanical stress between each pair of a functional die and a dummy die. In some embodiments, the substrate of the dummy die may comprise silicon, like the substrate of the functional die, or any other suitable type of semiconductor (e.g., silicon germanium, gallium arsenide) that may comprise implanted ions in order to have a similar CTE to that of silicon, and to improve the thermal conductivity of the dummy die.

In other embodiments, the substrate of the dummy die may comprise a suitable polymer having a CTE similar to that of the functional die (e.g., silicon). For example, the polymer substrate may comprise: (i) epoxy mold compound (EMC), (ii) EMC matrix with embedded. particles of silicon nitride, (iii) EMC matrix with embedded particles of silicon dioxide, (iv) EMC matrix with metal traces, (v) any suitable combination thereof, or any other suitable type of polymer having similar CTE to that of the substrate of the functional dies.

In alternative embodiments, the substrate of the dummy die may comprise a suitable ceramic material having a CTE similar to that of the functional die. For example, the ceramic substrate may comprise alumina, and/or silicon carbide having suitable additives configured to have the required CTE and to improve the thermal conductivity of the dummy substrate.

In some embodiments, at least a section of at least one of the dummy dies extends laterally beyond the edge of the stack, and the lid of the electronic device may have one or more openings, so that the extended section is extending laterally through the respective opening and thermally coupled with lid via thermal interface material between top surface of dummy die and lid opening surface. Several configurations of the extended sections of the dummy dies, and the structures of the respective lids, are described. in detail in FIGS. 1-5 below.

In some embodiments, the lid may comprise one or more cooling fins, which are configured to provide additional surface area on the lid for improving the heat dissipation from the stack of dies. Note that the lid having the cooling fins, may be implemented in any of the configurations described above.

The description. above is presented as a general overview of embodiments of the present disclosure, which are described in detail herein.

FIG. 1 is a schematic, sectional view of an electronic device 11, in accordance with an embodiment that is described herein.

In some embodiments, electronic device 11, also referred to herein as device 11 for brevity, comprises: (i) a substrate 29, typically a circuit board or any other suitable type of substrate, (ii) a substrate 33, and (iii) a stack 9 of dies, stacked on substrate 33 and described in detail hereinafter.

In some embodiments, substrate 33 comprises a suitable polymer or ceramic substrate and metal traces 27 patterned in the substrate. In the present example, the substrate comprises Ajinomoto Build-up Film® (ABF) laminate GL-102 produced by Ajinomoto Fine-Techno Co. Inc. (Kawasaki-shi, 210-0801, Japan), and metal traces 27 comprise copper or aluminum or any suitable alloy thereof, which are produced using any suitable processing techniques of circuit boards and integrated circuit (IC) substrates. In some embodiments, substrate has a thickness (i.e., along a Z-axis of an XYZ coordinate system) between about 0.4 mm and 3 mm.

In the context of the present disclosure and in the claims, the terms “about” or “approximately” for any numerical values or ranges indicate a suitable dimensional tolerance that allows the part or collection of components to function for its intended purpose as described herein.

In some embodiments, device 11 comprises solder balls 23 that are formed between substrates 33 and 29 and are configured to serve as terminals and to conduct electrical signals between substrates 33 and 29.

In some embodiments, stack 9 comprises one or more functional dies, in the present example four functional dies (FDs) 12, 13, 14 and 15. Each of FDs 12-15 comprises a semiconductor substrate (e.g., silicon, germanium, gallium arsenide) and functional electronic circuits (not shown). In some embodiments, FDs 12-15 are configured. to exchange electrical signals with substrate 33, and typically but not necessarily, also with one another.

In some embodiments, stack 9 comprises one or more dummy dies (DDs), which are disposed between substrate 33 and FD 15, which is the uppermost functional die of stack 9. In the present example, stack 9 comprises a dummy die (DD) 22, which is disposed between FDs 12 and 13.

In some embodiments, DD 22 is configured to dissipate heat generated by FDs 12 and 13, and to conduct electrical signals, such as but not limited to power signals, ground signals (i.e., connected to ground), and data signals exchanged. between two or more FDs of stack 9, and/or between one or more of the FDs and substrate 33.

In some embodiments, each of FDs 12-15 and DD 22 comprise through-silicon vias (TSVs) 24 for conducting electrical signals therethrough, at least along the Z-axis. At least one of TSVs 24 may be connected to ground, and other TSVs 24 may conduct power signals and data signals.

In some embodiments, stack 9 comprises terminals, in the present example, bumps 21, which are formed between every pair of the dies of stack 9, and also between FD 12 and substrate 33. Bumps 21 are configured to conduct the electrical signals between every pair of the dies of stack 9, and between FD 12 and substrate 33.

In some embodiments, each TSV 24 is formed between a respective pair of bumps 21 located along the Z-axis above and below the respective TSV 24. In other embodiments, two or more TSVs 24 may be connected to a single bump 21, e.g., via a redistribution layer (RDL) and/or via large pads (both not shown). Additionally, or alternatively, two or more bumps 21 may be routed to a single TSV 24 (e.g., via the aforementioned RDLs).

Additionally, or alternatively, one or more bumps 21 may be disconnected from TSVs 24 and may be formed for other purposes, for example, to maintain flatness of one or more of the dies of stack 9, which affects the reliability of electronic device 11.

In the present example, all TSVs may be similar in all FDs 12-15 and in DD 22. In other embodiments, at least one of FDs 12-15 and/or DD 22 may have different TSVs, based on the electronic specifications and the application of each FD. Moreover, the number of TSVs 24 may differ between the FDs. For example, a logic FD may have a different number of TSVs compared to that of a memory FD.

In some embodiments, at least one of and typically all FDs 12-15 have a silicon substrate. In the present, non-limiting, example, the coefficient of thermal expansion (CTE) of the silicon substrate is about. 2.6 ppm/° C. In order to prevent thermally induced mechanical stress between each. pair of a functional die and a dummy die, e.g., between FD 12 and DD 22, the CTE of DD 22 must be similar to that of FDs 12 and 13. In some embodiments, the substrate of DD 22 may comprise silicon, (like the substrate of FDs 12 and 13), or any other suitable type of semiconductor (e.g., germanium, gallium arsenide) that may comprise implanted ions or other sort of additives in order to have a similar CTE to that of silicon. Moreover, the implanted ions and/or additives (that may be inserted in diffusion or rapid thermal processes) may improve the thermal conductivity of DD 22.

In other embodiments, the substrate of DD 22 may comprise a suitable polymer having a CTE similar to that of silicon. For example, the polymer substrate may comprise: (i) epoxy mold compound (EMC), EMC matrix with embedded particles of silicon nitride, (ii) EMC matrix with embedded particles of silicon dioxide, (iv) EMC matrix with metal traces, (v) any suitable combination thereof, or any other suitable type of polymer having similar CTE to that of the substrate of one or more of the functional dies.

In some embodiments, the type of and concentration of the particles embedded in the EMC matrix, may alter the electrical conductivity of DD 22. In a non-limiting example, the thermal conductivity of a silicon wafer is about 2.3 W/mK, the thermal conductivity of EMC without additives is about 2.5 N/mK, and the thermal conductivity of EMC with additives may be between about 3 W/mK and 4 W/mK. In such embodiments, DD 22 comprising EMC with suitable embedded additives is configured to improve the dissipation of heat generated by one or more FDs 12-15 of stack 9. Note that after implanting p-type and/or n-type ions into the silicon substrate of a chip, the thermal conductivity may be increase to a typical value of about 117 W/mK.

In other embodiments, the substrate of DD 22 may comprise a suitable ceramic material having a CTE similar to that of the respective functional dies (e.g., at least FDs 12 and 13). For example, the ceramic substrate may comprise alumina, and/or silicon carbide having suitable additives configured to have CTE similar to about 2.6 ppm/° C., and to improve the thermal conductivity of the substrate of DD 22.

In some embodiments, device 11 comprises a lid 18, which is typically made from a suitable metal (e.g., nickel -plated copper) having a thickness (e.g., along the Z-axis) between about 0.3 mm and 3 mm. The metal-based lid 18 has high thermal conductivity, for example, the thermal conductivity of nickel is about 97 W/mK and the thermal conductivity of copper about 398 W/mK.

In the present example, the thickness of the plated nickel is about a few micro-inches, thus, the nickel-plated copper of lid 18 may have a thermal conductivity larger than about 390 W/mK. Note that the thickness ratio between the nickel and the copper, and the properties of the coating (which depends on the coating process) typically determine the thermal conductivity of lid 18.

In some embodiments, device 11 comprises a thermal interface material (TIM) disposed. between FD 15 and lid 18. In the present example, a TIM layer 16 comprises a silicone-based polymer having aluminum particles for improving the thermal conductivity of TIM layer 16, and having a thickness between about 20 μm and 150 μm.

In some embodiments, TIM layer 16 is formed over the surface of FD 15 (or over a passivation layer formed over the outer surface of FD 15), and an additional TIM layer, referred to herein as a TIM layer 17, is formed over the surface of a section of DD 22 to provide adequate thermal path from DD to lid 18.

In some embodiments, lid 18, which is formed using a stamping process (or any other suitable process), is assembled over TIM layers 16 and 17 for encapsulating stack 9. In some embodiments, device 11 comprises a stiffener 20, which is formed between DD 22 and substrate 33, and is made of a heat conducting material such as but not limited to nickel-plated copper or stainless steel.

In some embodiments, stiffener 20 is coupled to: (i) DD 22 and (ii) substrate using a suitable adhesive layer 19. In the present example, adhesive layer 19 comprises epoxy SE4450 produced by DuPont (Wilmington, Del.) having a thickness between about 50 μm and 200 μm.

In the example of device 11, stack 9 is confined between substrate 33 having low thermal conductivity (e.g., between about 10 W/mK and 15 W/mK), and lid 18 having very high thermal conductivity. In this configuration, device 11 is configured to dissipate most of the heat in a direction 7 through TIM layer 16 and lid 18, which is typically coupled to a heat sink (not shown) having cooling ribs. Thus, the heat generated by FDs 12, 13 and 14, is confined within stack 9.

In some embodiments, disposing one or more dummy dies having thermal conductivity larger than that of silicon (e.g., DD 22) , improves the dissipation of heat generated in stack 9 by FDs 12-15. Moreover, the geometric design of DD 22 (and of additional DDs optionally disposed between the FDs, as shown, for example, in FIGS. 2-7 below) may further improve the dissipation of heat generated by FDs 12-15.

In the example of FIG. 1, FDs 12-15 have all approximately an equal size along the X-axis of the XYZ coordinate system. This configuration is applicable, for example, in stacked memory devices, such as dynamic random-access memory (DRAM) devices, or in stacking multiple static RAM (SRAM) devices in stack 9. This configuration defines an edge 6 of stack 9. In some embodiments, the size or DD 22 is larger than that of at least one of, and. typically all FDs 12-15. As shown. in the example of FIG. 1, a section 30 of DD 22 extends laterally beyond edge 6 along the X-axis.

In other embodiments, stack 9 may comprise different types of dies having different sizes. In such embodiments, the size, and the position of DD 22 (and optionally additional DDs) along the Z-axis depends on the size, position, and the expected heat generation of each of the FDs in stack 9. For example, in case FD 14 comprises a processing die that generates more heat than the other FDs, DD 22 may be disposed between FDs 13 and 14, or between FDs 14 and 15.

In some embodiments, at least part of the heat generated by the functional dies (e.g., by FDs 12 and 13) is conducted by CD 22 in a. direction 5 (e.g., along the X-axis of DD 22) towards section 30, and dissipates in a direction 8 (e.g., along the Z-axis) through TIM layer 17 and lid 18. Additional embodiments related to heat dissipation and the configuration of device 11 are shown in FIG. 2 below, which is a top view of an AA section shown in FIG. 1.

In some embodiments, DD 22 comprises metal layers (shown and described in detail in FIG. 6 below) configured to dissipate heat generated by the one or more functional dies (e.g., by FDs 12 and 13). In other embodiments, DD 22 may comprise any other suitable heat conducting structures that improve the rate of heat dissipation through DD 22, at least in direction 5.

FIG. 2 is a schematic, top view of a plane AA of DD 22 in electronic device 11, in accordance with an embodiment that is described herein.

In some embodiments, based on the configuration presented in FIG. 1 above, FDs 12-15 have a major plane defined by at least first and second axial dimensions, in the present example, along the X- and Y-axes. In such embodiments, the axial dimension of DD 22 is greater than the first or second axial dimensions defining FDs 12-15. In the example of FIG. 2, a frame 37 defines the axial dimensions of DD 22 along the X- and Y-axes, and a frame 39 defines the axial dimensions of FDs 12-15 along the X- and Y-axes. In this configuration, the axial dimensions of FDs 12-15 and DD 22 are similar along the Y-axis. Along the x-axis, however, the axial dimension of DD 22 is larger than that of FDs 12-15. As shown in FIGS. 1 and 2, section 30 of DD 22 extends laterally beyond edge 6 of the FDs in stack 9.

In some embodiments, lid 18 of electronic device 11 may have one or more openings, so that the extended section 30 is extending laterally through the respective openings in lid 18. An example implementation of one or more openings is shown in a 3D schematic illustration and described in detail in. FIG. 5 below. In the example of FIG. 1 above, in addition. to the two openings in lid 18, electronic device 11 comprises stiffener 20, which is aligned with the corresponding sections of lid 18 along the Z-axis, and section 30 of DD 22 is extended between stiffener 20 and lid 18.

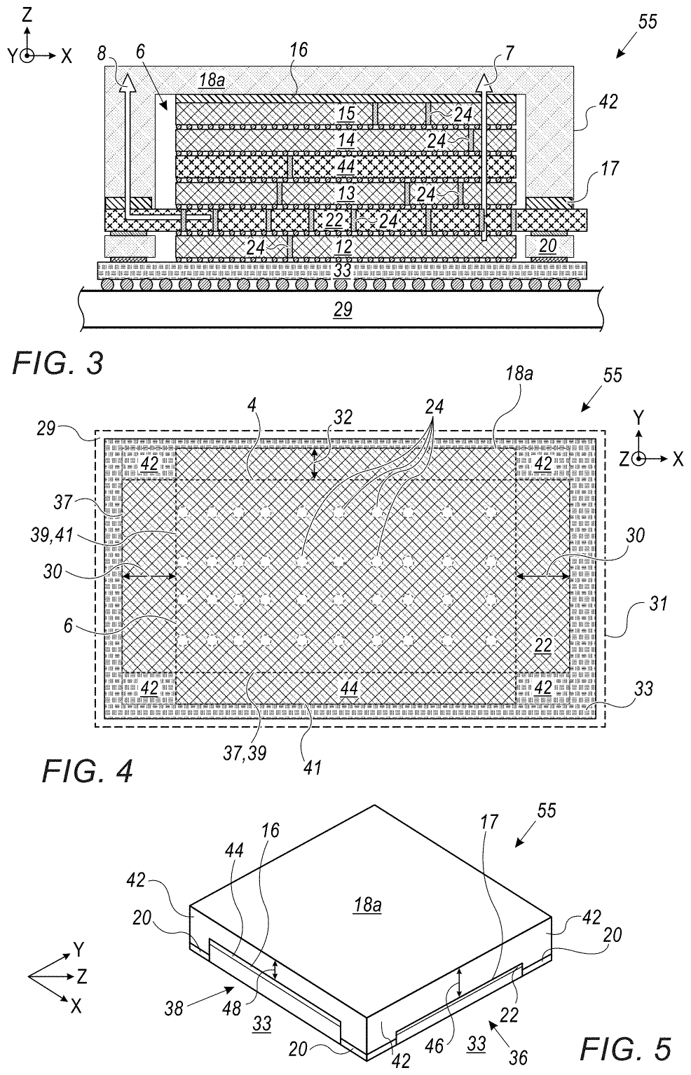

The configuration of electronic device 11 that is shown in FIGS. 1 and 2, is provided by way or example, in order to illustrate certain problems that are addressed by embodiments of the present disclosure and to demonstrate the application of these embodiments in enhancing the performance of such an electronic device having stacked dies. Embodiments of the present disclosure, however, are by no means limited to this specific sort of example electronic device, and the functional and dummy dies, and electrical connections, and the principles described herein may similarly be applied to other sorts of die-stacking configurations in electronic devices, as will be shown in FIGS. 3-7 below.

FIG. 3 is a schematic, sectional view of an electronic device 55, in accordance with another embodiment that is described herein. In some embodiments, the structure of electronic device 55 is similar to that of electronic device 11 with at least one difference. Electronic device 55 comprises an additional dummy die, referred to herein as DD 44, which is disposed between FDs 13 and 14.

In the present example, the axial dimension of DD 44 is similar to that of FDs 12-15 along the X-axis, but is greater than that of FDs 12-15 along the Y-axis, as will be shown in FIG. 4 below, which is the top view of electronic device 55. As shown in the sectional view of FIG. 3, DD 44 does not extend laterally beyond edge 6 of the FDs in stack 9, but extends laterally along the Y-axis beyond another edge of stack 9, as will be described in FIG. 4 below.

In some embodiments, electronic device 55 comprises a lid 18a, which is made from the same materials of lid 18 of FIGS. 1 and 2 above, and is formed using similar processes. However, lid 18a has four openings, which are defined. between four legs 42 of lid 18a, as will be described in detail in FIG. 5 below.

FIG. 4 is a schematic, top view of electronic device 55, in accordance with an embodiment that is described herein. As described in FIG. 2 above, frame 37 defines the axial dimensions of PD 22 along the X- and Y-axes, and frame 39 defines the axial dimensions of FDs 12-15 along the X- and Y-axes.

In some embodiments, a frame 41 defines the axial dimensions of DD 44 along the X- and Y-axes. In this configuration, the axial dimensions of FDs 12-15 and DD 44 are similar along the X-axis, but along the Y-axis, the axial dimension of DD 44 is larger than that of FDs 12-15, and a section 32 of DD 44 extends laterally along the Y-axis beyond an edge 4 of the FDs in stack 9.

In other embodiments, at least one of sections 30 and 32 may exceed the edge of substrate 33. In this configuration the size of lid 18a may be larger than that of substrate 33, at least along one of the X- and Y-axes, so as to encapsulate one or both DDs 22 and 44.

In some embodiments, lid 18a has four openings, which are defined in XY plane, between legs 42 of lid 18a, as wail be described in detail in FIG. 5 below.

The configuration. of electronic device 55 that shown in FIGS. 3 and 4, is provided by way of example, in order to illustrate certain problems that are addressed by embodiments of the present disclosure and to demonstrate the application of these embodiments in enhancing the performance of such an electronic device. Embodiments of the present disclosure, however, are by no means limited to this specific sort of example electronic device, functional dies and dummy dies, and the principles described. herein may similarly be applied to other sorts of electronic devices having any suitable types of dies stacked on a substrate and packaged.

FIG. 5 is a schematic, pictorial illustration of electronic device 55, in accordance with an embodiment that is described herein.

In some embodiments, lid 18a of electronic device 55 has four openings, referred to herein as openings 36 and 38, each of which has two openings facing one another along X- and Y-axes. In this configuration, sections 30 and 32 of DDs 22 and 44 are extending laterally through the openings in lid 18a along the X- and Y-axes, respectively.

In some embodiments, TIM layer 16 is disposed between DD 44 and lid 18a, and TIM layer 17 is disposed between CD 44 and lid 18a, so as to improve the thermal conductivity therebetween. Note that in the example configuration. of FIG. 3 above, TIM layer 16 is disposed on FD 15, but is also extended along the Y-axis, to cover the upper surface of DC 44, which is extended along the Y-axis relative to FDs 14 and 15. In other words, TIM layer 16 is disposed (i) between. lid 18a and FD 15 (as shown in the sectional view of FIG. 3 above), and (ii) between lid 18a and DD 44 (as shown in the schematic pictorial illustration of FIG. 5).

In some embodiments, openings 36 and 38 of lid 18a are defined: (i) in NY plane between legs 42 of lid 18a, and (ii) along the Z-axis between the surface of substrate 33 and the lower surface of lid 18a at the respective opening. Note that because DD 44 is located higher than DD 22 along the Z-axis of stack 9, a thickness 48 of opening 38 is smaller than a thickness 46 of opening 36, so that along the Z-axis, opening 36 is smaller than opening 38. Moreover, DD 44 extends into opening 38, and therefore, DD 22 and FDs 12 and 13 are not visible through opening 38 because they are hidden behind the structure of lid 18a. Similarly, in opening 36, the edge of DD 22 is shown, but the edge of FD 12 is hidden behind the structure of lid 18a.

The configuration of lid 18a that shown in FIG. 3-5 is provided by way of example, in order to illustrate certain problems that are addressed by embodiments of the present disclosure and to demonstrate the application of these embodiments in enhancing the performance of such an electronic device. Embodiments of the present disclosure, however, are by no means limited to this specific sort of example lid, and the principles described herein may similarly be applied to other sorts of lids implemented in other sorts of electronic devices having any suitable types of stacked dies that are at least partially encapsulated using a suitable lid.

FIG. 6 a schematic, sectional view of an electronic device 66, in accordance with another embodiment that is described herein.

In some embodiments, electronic devise 66 comprises substrate 29 (shown in FIGS. 1 and 3 above), substrate 33, TIM layers 16 and 17, adhesive layers 19, stiffener 20, TSVs 24, FDs 12-15, and a lid 18b, which is similar to lids 18 and 18a, but may have different openings.

In some embodiments, electronic device 66 comprises a DD 88, which is disposed between FDs 12 and 13 and extends beyond the edge of the stacked FDs along the Y-axis, as shown and described in FIGS. 3-5 above for DC 44.

Electronic device 66 further comprises DD 99, which is disposed between FDs 13 and 14 and extends beyond the edge of the stacked FDs along the X-axis, as shown and described in detail for DD 44 in FIGS. 3-5 above.

In some embodiments, the terminals of electronic device 66, e.g., the bumps disposed between each pair of the functional and dummy dies, are similar to bumps 21 of FIG. 1 above, and the solder balls disposed on the outer surface of substrate 33, are similar to solder balls 23 of FIG. 1 above.

Reference is now made to an inset 61 showing a sectional view of at least one of the dummy dies, in the present example, of DDs 88 and 99.

In some embodiments, at least one of and typically both DDs 88 and.99 comprise an intra-stack capacitor, referred to herein as a capacitor 60. In the present example, capacitor 60 comprises a first metal layer 62 and a second metal layer 64, also referred to herein as a power plane and a ground plane, respectively, and a dielectric layer 68 formed between layers 62 and 64.

In some embodiments, layers 62 and 64 are electrically disconnected from one another by layer 68. In the present example, layer 68 is part of the substrate material of the respective dummy die (e.g., DD 88 and/or DD 99). Note that the substrate material may comprise semiconductor, polymer or ceramic materials as described in FIG. 1 above.

In other embodiments, layer 68 may comprise any other suitable type of dielectric layer, which is formed between metal layers 62 and 64 in order to obtain the required capacitance properties of capacitor 60 (e.g., capacitance value between one nanofarad (nF) and any suitable number of microfarads (μF)).

In some embodiments, metal layers 62 and 64 are electrically coupled, respectively, to first and second electrical connections of electronic device 66. In the present example, the first electrical connections are implemented as first TSVs 72, also referred to herein as power TSVs. Similarly, the second electrical connections are implemented as second TSVs 74, also referred to herein as ground TSVs. Note that the power plane and power TSVs are configured to conduct power signals, and the ground plane and ground TSVs are electrically connected to ground.

In some embodiments, both DDs 88 and 99 further comprise one or more TSVs 24, which are electrically decoupled from metal layers 62 and 64 and from TSVs 72 and 74, and are configured to conduct data signals through DDS 88 and 99.

In some embodiments, the electrical connections further comprise the bumps disposed between each pair of dies and between FD 12 and substrate 33, and pads connecting between the TSVs and the bumps. In the present example, power pads 76 (described in more detail hereinafter) are connecting between the bumps and TSVs 72, ground pads 78 are connecting between the bumps and TSVs 74, and data pads 79 are connecting between the bumps and TSVs 24.

Reference is now made to insets 63 and 65 that are showing top views of layers 62 and 64, respectively. Referring to inset 63, in some embodiments, TSV 72 that conducts power signals, is electrically coupled. to layer 62, and therefore, shown in a dashed circle. TSVs 24 and 74 that conduct data signals and connected to ground, respectively, are surrounded by a suitable dielectric layer 70 (e.g., silicon dioxide) for electrically decoupling them from layer 62.

Referring to inset 65, in some embodiments, TSV 74 that is connected to ground, is electrically coupled to layer 64, and therefore, shown in a dashed circle. TSVs 24 and 72 that conduct data signals and power signals, respectively, are surrounded by dielectric layer 70 for electrically decoupling them from layer 64.

Reference is now made back to inset 61. In some embodiments, metal layers 62 and 64 are configured to dissipate at least part of the heat generated by one or more of the functional dies. For example, in DD 99, metal layers 62 and 64 dissipate heat generated by at least FDs 13 and 14. The heat is conducted from FDs 13 and 14 along the Z-axis through (the bumps, pads and) TSVs 72 and 74 to metal layers 62 and 64, respectively. Metal layers 62 and 64 conduct the heat laterally toward the edge of DD 99 and the stack, and lid 18b dissipates the heat along the Z-axis.

In some embodiments, TSVs 72 comprise one or more power rails that are electrically coupled to metal layer 62, and TSVs 74 comprise one or more ground rails that are electrically coupled to metal layer 64. In the present example, metal layers 62 and 64 form (together with layer 68) capacitor 60 for mitigating electrostatic discharge (ESD) effects within. electronic device 66. For example, in case an undesired power spike is formed in electronic device 66, capacitor 60 is configured to mitigate the effects of the power spike on at least one of FDs 12-15.

In some embodiments, capacitor 60 is configured to store electrical power, and if necessary, to supply power to at least one of FDs 12-15. For example, capacitor 60 of DD 99 may store electrical power received from substrate 33, and subsequently, capacitor 60 may supply the stored power to FD 14. Note that the amount of power that can be stored, and subsequently supplied, is limited by the capacitance of capacitor 60.

Electronic device 66 and other sorts of stacked-die electronic devices, may comprise an ESD protection device used in a power pad. In the present example, the power pads (e.g., power pads 78) that are intended to conduct power signals, typically comprise an RC-triggered power clamp, which comprises at least: (i) a resistor and a capacitor arranged in a serial configuration, and (ii) multiple buffers configured to drive a transistor located between the power pad and the ground. This configuration typically results in large-sized. power pads (e.g., about 50 μm by 50 μm, or about 10 μm by 10 μm, depending on the technology node). In some embodiments, the in-stack capacitor (e.g., capacitor 60) is designed to have sufficient capacitance so that the RC-triggered power clamps are not required. In such embodiments, the size of the power pads (e.g., power pads 78) may be reduced between about 20% and 80%. For example, by implementing the in-stack capacitor (e.g., capacitor 60) the size of a given. power pad 78 may be reduced from about 20 μm by 20 μm to a size of about 10 μm by 10 μm.

Reference is now made to an inset 28 showing a top view of a cell comprising one TSV 24 in a BB-section of ED (e.g., ED 15). Typically, due to insufficient cooling of one or more of FDs 12-15, the thermal cycles cause expansion and shrinkage of the TSVs, resulting in mechanical stress induced into the respective FDs. Such mechanical stress may cause shifts in the electrical performance of active devices formed on a surface 25 of the one or more respective FDs (in the present example, of FD 15). For example, a shift in electrical performance may comprise a different threshold voltage or breakdown voltage of a field-effect transistor (FET) (e.g., fin FET). In order to prevent such effects, a keep-out zone is defined around every TSV. For example, in a device that does not have dummy dies for dissipating heat and reducing and for mitigating ESD effects, the size of the keep-out zone may be larger than about 2 μm and can be as large as about 10 μm around every TSV of FDs 12-15.

In some embodiments, the size of the keep-out zone may be reduced by: (i) improving the heat dissipation using the dummy die techniques described above, and (ii) forming dielectric layer 70 that is surrounding the TSV along the Z-axis, as also described in insets 63 and 65 above. In such embodiments, a larger area of the functional dies may be used for active devices, such as transistors and. memory cells.

The configuration of capacitor 60 is provided by way of example, in order to illustrate certain problems, such as but not limited to heat dissipation and capacitance in dummy dies that are addressed embodiments of the present disclosure and to demonstrate the application of these embodiments in enhancing the performance of electronic device 66, as well as the other electronic devices shown in FIGS. 1-5 and 7 of the present disclosure. Embodiments of the present disclosure, however, are by no means limited to this specific sort of example capacitor and TSVs, and the principles described herein may similarly be applied to other sorts of capacitors implemented in other sorts of dummy dies and electronic devices having any suitable types of stacked dies.

For example, in capacitor 60, metal layers 62 and 64 are formed parallel to one another (e.g., parallel to the X-axis) and the longitudinal axes of the TSVs are orthogonal to metal layers 62 and 64 (e.g., parallel to the Y-axis). In other embodiments, metal layers 62 and 64 may not be parallel to one another (i.e., at least one of metal lines may not be parallel to the X-axis and/or at least one of the TSVs may not be parallel to the Y-axis.

In alternative embodiments, metal layers 62 and 64 may be parallel to one another but may not be parallel to the XY plane. Moreover, at least one of the dummy dies (e.g., one or both of DDs 88) may comprise a deep trench capacitor (DTC) configured to mitigate electrostatic discharge (ESD) effects within electronic device 66.

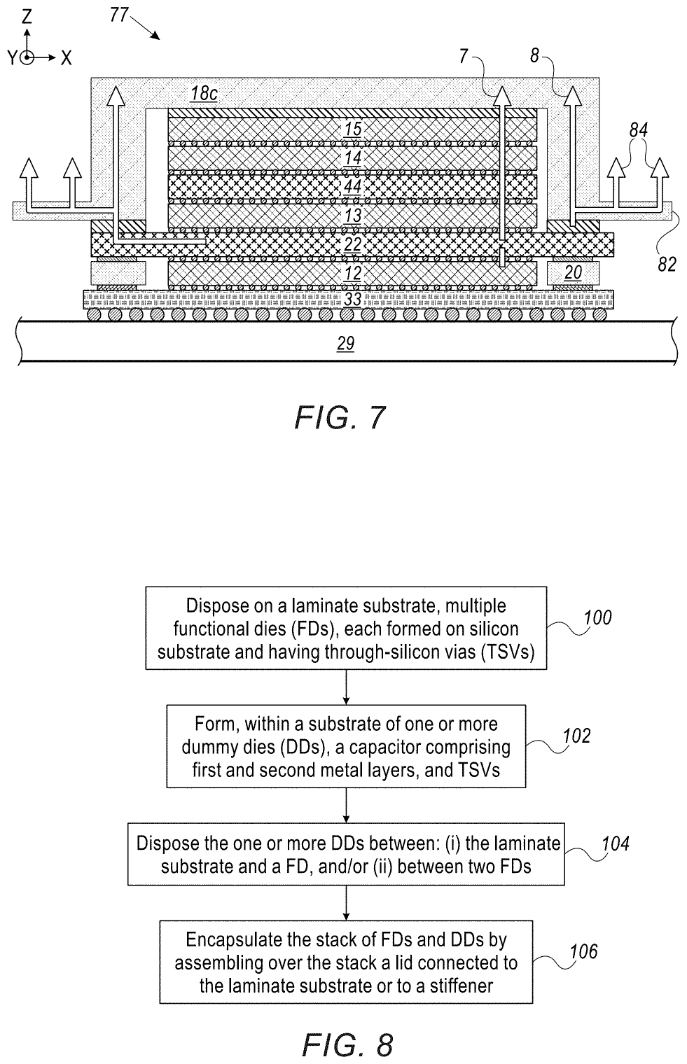

FIG. 7 is a schematic, sectional view of an electronic device 77, in accordance with an alternative embodiment that is described herein.

In some embodiments, electronic device 77 may comprise the same structure of the stack of dies shown in FIG. 3 above (i.e., FDs 12-15, DD 22 between FDs 12 and 13, and DD 44 between FDs 13 and 14), or any other suitable configuration of the stacked dies. Moreover, electronic device 77 may comprise the same structure of substrates 33 and 29, and the same bumps and balls described in FIGS. 1-6 above.

In some embodiments, electronic device 77 comprises a lid 18c, which comprises one or more cooling fins 82, which are configured to provide additional surface area on lid 18c (as compared to lids 18, 18a and 18b shown in FIGS. 1-6 above). As shown in the present example, cooling fins 82 are extended along the X-axis for improving the heat dissipation from the stack of functional dies 12-14, through dummy dies 22 and 44, in a direction 84 (which is parallel to the Y-axis).

In some embodiments, cooling fins 82 may comprise a two-dimensional (2D) shelf structure having an axial dimension (along the Y-axis) that is larger than that of the stack of dies.

In other embodiments, lid 18c may comprise multiple cooling fins 82 that are shaped as lines or rods, formed along the Y-axis of lid 18c, and having air gaps therebetween.

In alternative embodiments, lid 18c may comprise multiple cooling fins 82 positioned at different heights along the Z-axis and the X-axis and/or Y-axis of the legs of lid 18c. For example, first cooling fins 82 located in proximity to DD 22 (as shown in FIG. 7) and second cooling fins (not shown) located in proximity to DD 44. Moreover, at least two of the first and second cooling fins may have a different size along at least one of the X-axis and/or the Y-axis.

Additionally, or alternatively, lid 18c may comprise cooling fins (not shown) that are extended along the Y-axis of the XYZ coordinate system of electronic device 77, so as to provide additional surface area on lid 18c and further improve the heat dissipation for the stack of functional and dummy dies.

In alternative embodiments, cooling fins 82 may surround at least part of and typically the entire perimeter of the stacked dies and the legs of lid 18c.

In some embodiments, the structure of lid 18c that has the cooling fins extended in the XY plane and/or in any other direction, which may be parallel to the X- or Y-axes, or alternatively, not parallel to the X- or Y-axes, may be implemented in any of the configurations of lids 18, 18a and 18b described in FIGS. 1-6 above.

The configuration of lid 18c is provided by war of example, in order to illustrate certain problems, such as heat dissipation that are addressed by embodiments of the present disclosure and to demonstrate the application of these embodiments in enhancing the performance of electronic device 77, and optionally, in the other electronic devices shown in FIGS. 1-6 above. Embodiments of the present disclosure, however, are by no means limited to this specific sort of example lid structure, and the principles described herein may similarly be applied to other sorts of lids implemented in other sorts of electronic devices having any suitable types of stacked dies.

Additionally, or alternatively, electronic device 77 may comprise additional cooling fins that are extended from stiffener 20. Such cooling fins may have any suitable configuration, such as but not limited to one or more of the cooling fins configurations described above.

FIG. 8 is a flow chart that schematically illustrates a method for producing electronic device 66, in accordance with an embodiment that is described herein.

The method begins at a functional die disposing operation 100 with disposing FD 12 over the bumps and substrate 33, as described in detail in FIGS. 1, 3 and 6 above.

At a dummy die formation operation 102, dummy dies 88 and 99 are formed by producing: (i) capacitor 60 comprising metal layers 62 and 64 and dielectric layer 68, and (ii) TSVs 72 and 74 (electrically coupled with layers 62 and 64, respectively), and TSVs 24, as described in detail in FIG. 6 above. Note that the formation of dummy dies 88 and 99 may be carried out prior to the disposing of functional die 12 over substrate 33.

At a dummy die disposing operation 104, dummy die 88 is disposed between FDs 12 and 13, and dummy die 99 is disposed between FDs 13 and 14, as described in FIG. 6 above. Additionally, or alternatively, a dummy die (e.g., similar to DDs 88 and 99) may be disposed between substrate 33 and FD 12.

In some embodiments, stiffener 20 and adhesive layers 19 are disposed between substrate 33 and at least one of DDs 88 and 99 in order to improve the stiffness of electronic device 66, as described in detail in FIGS. 1 and 6 above. Subsequently, FD 15 is disposed over FD 14, and TIM layers 16 and 17 are formed over the surface of FD 15 and DD 99, respectively, as described in detail, for example, in FIG. 1 above. Additionally, or alternatively, a dummy die (e.g., similar to DDs 88 and 99) may be disposed between FDs 14 and 15.

At an encapsulation operation 106 that concludes the method, lid 18b or any other suitable lid (such as lid 18, 18b or 18c described above) , is assembled over the stack of dies. In some embodiments, lid 18b is disposed over stiffener 20.

In other embodiments, a different lid having a different shape may be used for encapsulating the stack of dies. This lid may be directly disposed over an adhesive layer (not shown) formed over substrate 33. In this configuration, stiffener 20 may be eliminated and the lid is assembled over substrate 33.

The operations of the method of FIG. 8 are simplified for the sake of conceptual clarity and are provided by way of example. Embodiments of the present disclosure, however, are by no means limited to this specific sort of fabrication technique, and the principles described herein may similarly be applied to other sorts of methods used for producing an electronic device comprising a stack of functional dies and dummy dies. Moreover, the method of FIG. 8 typically comprises additional operations, such as but not limited to surface preparation (e.g., before deposition of layers), cleaning of residues, the formation of the pads (e.g., Pads 76, 78 and 79) and the formation of the halls (between substrates 33 and 29) and the bumps (between substrate 33 and FD 12, and between any pair of dies in the stack), as described in detail in FIGS. 1-7 above.

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explictly or implicitly in the present specification, only the definitions in the present specification should be considered.

1. An electronic device, comprising:
a substrate; and
a stack of dies stacked on the substrate, the stack comprising:
one or more functional dies, the functional dies including functional electronic circuits and being configured to exchange electrical signals at least with the substrate; and
one or more dummy dies, the dummy dies being disposed among dies forming the stack and being configured to: (i) dissipate heat generated by the one or more functional dies and (ii) pass electrical signals exchanged between the substrate and the one or more functional dies or between two or more of the functional dies.

2. The electronic device according to claim 1, wherein at least one of the dummy dies comprises first and second metal layers, which are: (i) electrically disconnected from one another, (ii) electrically coupled, respectively, to first and second electrical connections of the electronic device, and (iii) configured to dissipate at least part of the heat generated by at least one of the functional dies.

3. The electronic device according to claim 2, wherein the first electrical connections comprise one or more power rails electrically coupled to the first metal layer, wherein the second electrical connections comprise one or more ground rails electrically coupled to the second metal layer, and wherein the first and second metal layers form an intra-stack capacitor for mitigating electrostatic discharge (ESD) effects within the electronic device.

4. The electronic device according to claim 2, wherein the first and second metal layers, form an intra-stack capacitor configured to supply power to at least one of the functional dies.

5. The electronic device according to claim 1, wherein the dummy dies comprise one or both of: (i) a first dummy die disposed between the substrate and a first one of the functional dies, and (ii) a second dummy die disposed between two of the functional dies.

6. The electronic device according to claim 1, wherein the functional dies have a major plane defined by at least first and second axial dimensions, wherein an axial dimension of at least one of the dummy dies is greater than the first or second axial dimensions defining the functional dies.

7. The electronic device according to claim 6, wherein the dummy dies comprise a first dummy die having a first axial dimension of the first dummy die, which is larger than the first axial dimension of the functional dies, and a second dummy die having a second axial dimension, which is larger than the second axial dimension of the functional dies.

8. The electronic device according to claim 6, comprising a lid, which is configured to: (i) encapsulate at least part of the stack, and (ii) dissipate heat from the electronic device.

9. The electronic device according to claim 8, wherein at least a part of one of the dummy dies extends laterally beyond an edge of the stack and wherein the lid has at least one opening, the part is extending laterally through the opening, and is thermally coupled to the lid at the opening.

10. The electronic device according to claim 9, comprising a thermal interface material (TIM) disposed between the lid and the part of one of the dummy dies, the TIM configured to thermally couple between the lid and the part of one of the dummy dies.

11. The electronic device according to claim 8, wherein the lid has one or more cooling fins, which are configured to provide an additional surface area on the lid for heat dissipation.

12. The electronic device according to claim 1, comprising a stiffener formed between the substrate and the lid, the stiffener being configured to improve a mechanical stiffness of the electronic device.

13. The electronic device according to claim 1, wherein at least one of the dummy dies comprises a semiconductor substrate.

14. The electronic device according to claim 1, wherein at least one of the dummy dies comprises a polymer substrate.

15. The electronic device according to claim 1, wherein at least one of the dummy dies comprises a ceramic substrate.

16. A method for producing an electronic device, the method comprising:
disposing, on a substrate a stack of dies, the stack comprising one or more functional dies, the functional dies including functional electronic circuits for exchanging electrical signals at least with the substrate; and
disposing, on the substrate among the dies forming the stack, one or more dummy dies for: (i) dissipating heat generated by the one or more functional dies, and (ii) passing electrical signals exchanged between the substrate and the one or more functional dies or between two or more of the functional dies.

17. The method according to claim 16, comprising, forming in at least one of the dummy dies, first and second metal layers, which are: (i) electrically disconnected from one another, and (ii) electrically coupled, respectively, to first and second electrical connections of the electronic device for dissipating at least part of the heat generated by at least one of the functional dies.

18. The method according to claim 17, wherein the first electrical connections comprise one or more power rails electrically coupled to the first metal layer, wherein the second electrical connections comprise one or more ground rails electrically coupled to the second metal layer, and wherein forming the first and second metal layers comprises forming an in capacitor for mitigating electrostatic discharge (ESD) effects within the electronic device.

19. The method according to claim 17, wherein forming the first and second metal layers comprises forming an intra-stack capacitor for supplying power to at least one of the functional dies.

20. The method according to claim 16, wherein disposing the dummy dies comprises one or both of: (i) disposing a first dummy die between the substrate and a first one of the functional dies, and (ii) disposing a second dummy die between two of the functional dies.

21. The method according to claim 16, wherein the functional dies have a major plane defined by at least first and second axial dimensions, and wherein disposing the dummy dies comprises selecting the one or more dummy dies such that an axial dimension of at least one of the dummy dies is greater than the first or second axial dimensions defining the functional dies.

22. The method according to claim 21, wherein selecting the dummy dies comprises selecting a first dummy die having a first axial dimension, which is larger than the first axial dimension of the functional dies, and selecting a second dummy die having a second axial dimension, which is larger than the second axial dimension of the functional dies.

23. The method according to claim 21, comprising assembling, over at least the stack, a lid for: (i) encapsulating at least part of the stack, and (ii) dissipating heat from the electronic device.

24. The method according to claim 23, wherein at least a part of one of the dummy dies extends laterally beyond an edge of the stack, and wherein the lid has at least one opening, the part is extending laterally through the opening of the lid, and is thermally coupled to the lid at the opening.

25. The method according to claim 24, comprising disposing a thermal interface material (TIM) between the lid and the part of one of the dummy dies for thermally coupling between the lid and the part of one of the dummy dies.

26. The method according to claim 24, wherein assembling the lid comprises selecting the lid having one or more cooling fins that provide an additional surface area on the lid for heat dissipation.

27. The method according to claim 16, comprising forming a stiffener, between the substrate and the lid, for improving a mechanical stiffness of the electronic device.

28. The method according to claim 16, wherein disposing the one or more dummy dies comprises disposing at least one of the dummy dies having a semiconductor substrate.

29. The method according to claim 16, wherein disposing the one or more dummy dies comprises disposing at least one of the dummy dies having a polymer

30. The method according to claim 16, wherein disposing the one or more dummy dies comprises disposing at least one of the dummy dies having a ceramic substrate.
